(19) United States
(12) Patent Application Publication
(10) Pub. No.: US 2009/0273671 A1
(43) Pub. Date: Nov. 5, 2009

(54) METHOD AND APPARATUS FOR ENCAPSULATING DIGITAL AERIAL SURVEILLANCE VIDEO ON ANALOG VIDEO SIGNAL

(75) Inventor: Steven H. Gardner, San Diego, CA (US)

Correspondence Address: TOWNSEND AND TOWNSEND AND CREW LLP;VIASAT, INC. (CLIENT #017018), TWO EMBARCADERO CENTER, 8TH FLOOR, SAN FRANCISCO, CA, 94111, US

(73) Assignee: ViaSat, Inc., Carlsbad, CA (US)

(21) Appl. No.: 12/372,527

(22) Filed: Feb. 17, 2009

Related U.S. Application Data
(60) Provisional application No. 61/029,280, filed on Feb. 15, 2008.

(51) Int. Cl. H04N 7/18; H03M 1/12

(52) U.S. Cl. 348/144; 348/572; 348/E07.085; 348/E05.062

(57) ABSTRACT

An aerial surveillance apparatus for processing an analog video signal is described. The aerial surveillance apparatus includes a first input configured to receive an analog video signal from a video camera, a processor coupled with the analog video signal and configured to filter and digitize the analog video signal to form a de-emphasized digital signal, an output configured to couple to an FM video transmitter and to communicate the de-emphasized digital signal to the FM video transmitter. The filtering of the processor decreases amplitudes of higher frequencies within a band of frequencies more than amplitudes of lower frequencies within the band of frequencies, and the FM video transmitter filters the de-emphasized digital signal using a pre-emphasis filter that counteracts the filtering of the de-emphasis filter. The aerial surveillance apparatus may further include a second input configured to receive a digital data signal, the processor combines the digitized video signal and the digital data signal prior to the filtering to form a combined signal, and the processor filters the combined signal to form the de-emphasized digital signal.

This application claims the benefit of U.S. Provisional Application Ser. No. 61/029,280 filed on Feb. 15, 2008 and entitled “DIGITAL VIDEO ENCAPSULATED ON ANALOG VIDEO SIGNAL, which is expressly incorporated by reference in its entirety for all purposes.

### BACKGROUND

This disclosure relates in general to wireless communication of aerial surveillance video and, but not by way of limitation, to communication of digitized aerial surveillance video over analog FM wireless video links.

Many aerial vehicles (AVs), including manned (MAVs) or unmanned (UAVs) use analog frequency modulation (FM) video communication systems. In these analog FM video systems, the analog video signal frequency modulates a carrier of the analog FM signal. FM is common in analog broadcast radio and television transmission.

These analog FM communication systems suffer from several deficiencies. For example, there is no security, e.g., encryption, provided by analog FM communications. Eavesdropping is as simple as buying an off-the-shelf FM receiver and tuning to the correct carrier frequency. In addition, analog FM communications exhibit poor signal to noise ratio (SNR) which limits the communication range.

### SUMMARY

In one embodiment, an aerial vehicle system including a wireless data link is disclosed. An analog video transmitter receives what it believes is an analog video signal, but actually encapsulates digital information on that analog video signal. The digital information includes a digitized video signal and possibly other information. A digital encoder module receives the analog video signal and reformulates the digitized video signal and any other information. In an upgrade application, the digital encoder module can increase throughput or signal robustness of the wireless link, for example.

In another embodiment, an aerial surveillance apparatus for processing an analog video signal is disclosed. The aerial surveillance apparatus of this embodiment includes a first input configured to receive an analog video signal from a video camera, a processor coupled with the analog video signal and configured to filter and digitize the analog video signal to form a de-emphasized digital signal. The aerial surveillance apparatus includes an output configured to couple to an FM video transmitter and to communicate the de-emphasized digital signal to the FM video transmitter, where the filtering of the processor decreases amplitudes of higher frequencies within a band of frequencies more than amplitudes of lower frequencies within the band of frequencies, and the FM video transmitter filters the de-emphasized digital signal using a pre-emphasis filter that counteracts the filtering of the de-emphasis filter.

In another embodiment, an aerial surveillance apparatus for processing a digital video signal to produce an analog video signal is disclosed. The aerial surveillance apparatus of this embodiment includes a first input coupled with a FM video receiver and configured to receive a digital video signal from the FM video receiver, where the digital video signal is demodulated from a carrier signal, the digital video signal was filtered with a de-emphasis filter of the FM video receiver, and the de-emphasis filter decreases amplitudes of higher frequencies within a band of frequencies more than amplitudes of lower frequencies within the band of frequencies. The aerial surveillance apparatus includes a processor coupled with the first input and configured to filter the digital video signal, where the filtering counteracts the filtering of the de-emphasis filter of the FM video receiver, and process the digital video signal to produce an analog video signal. The aerial surveillance apparatus further includes a first output coupled with the processor and configured to couple to an analog video system and to communicate the analog video signal to the analog video system.

In another embodiment, an aerial surveillance apparatus for processing an analog video signal is disclosed. The aerial surveillance apparatus of this embodiment includes a first input configured to receive the analog video signal from a video camera, a second input configured to receive a digital data signal, and a digitizer coupled with the first input and configured to digitize the analog video signal to form a digital video signal. The aerial surveillance apparatus further includes a combiner coupled with the digitizer and the second input, the combiner configured to combine the digital video signal and the digital data signal to form a combined signal, a Gaussian filter coupled with the combiner and configured to filter the combined signal to form a filtered combined signal, and an output coupled with the Gaussian filter and configured to couple to a FM video transmitter, the output configured to communicate the filtered combined signal to the FM video transmitter.

In another embodiment, an aerial surveillance apparatus for processing a digital video signal and a digital data signal is disclosed. The aerial surveillance apparatus of this embodiment includes an input coupled with a FM video receiver and configured to receive a digital signal from the FM video receiver, the digital signal comprising Gaussian filtered baseband symbols representing bit values of the digital video signal and bit values of the digital data signal, a processor coupled with the input and configured to process the Gaussian filtered baseband symbols to determine the bit values of the digital video signal and the digital data signal. The aerial surveillance apparatus further includes a divider coupled with the processor and configured to separate the digital video signal from the digital data signal, a video processing system coupled with the divider and configured to process the digital video signal to produce an analog video signal, a first output coupled with the video processing system and configured to couple to an analog video system and to communicate the analog video signal to the analog video system, and a second output coupled with the divider and configured to couple the digital data signal.

In another embodiment, a method of processing an analog aerial surveillance video is disclosed. The method of this embodiment includes receiving a video signal from an analog video camera, digitizing the video signal to form a digital video signal, and filtering the video signal with a de-emphasis filter to form a de-emphasized digital signal, where the de-emphasis filtering decreases amplitudes of higher frequencies within a band of frequencies more than amplitudes of lower frequencies within the band of frequencies. The method further includes communicating the de-emphasized digital signal to an FM video transmitter, where the FM video transmitter filters the de-emphasized digital signal using a pre-emphasis filter that counteracts the de-emphasis filtering of the de-emphasized digital signal.

In another embodiment, a method of processing an analog aerial surveillance video is disclosed. The method of this embodiment includes receiving an analog video signal from a video camera, receiving a digital data signal, digitizing the analog video signal to form a digital video signal, combining the digital video signal and the digital data signal to form a combined signal, filtering the combined signal with a Gaussian filter to form a filtered combined signal, and communicating the filtered combined signal to an FM video transmitter.

In yet another embodiment, a method of processing a digital video signal to produce an analog video signal is disclosed. The method of this embodiment includes receiving a digital video signal from a FM video receiver, where the digital video signal is demodulated from a carrier signal, the digital video signal was filtered with a de-emphasis filter of the FM video receiver, and the de-emphasis filter decreases amplitudes of higher frequencies within a band of frequencies more than amplitudes of lower frequencies within the band of frequencies. The method further includes filtering the digital video signal, wherein the filtering counteracts the filtering of the de-emphasis filter of the FM video receiver, processing the digital video signal to produce an analog video signal, and communicating the analog video signal to an analog video system.

Further areas of applicability of the present disclosure will become apparent from the detailed description provided hereinafter. It should be understood that the detailed description and specific examples, while indicating various embodiments, are intended for purposes of illustration only and are not intended to necessarily limit the scope of the disclosure.

### BRIEF DESCRIPTION OF THE DRAWINGS

The present disclosure is described in conjunction with the appended figures.

FIG. 1 is an embodiment of an aerial surveillance system that includes an analog FM communication link.

FIG. 2 is a functional block diagram of an embodiment of a system for providing a digitized aerial surveillance video for transmission over the analog FM communication link of FIG. 1.

FIG. 3 is a functional block diagram of an embodiment of a system for processing a digitized aerial surveillance video received over the analog FM communication link of FIG. 1.

FIG. 4 is a flowchart of an embodiment of a process for providing a digitized aerial surveillance video for transmission over the analog FM communication link of FIG. 1.

FIG. 5 is a flowchart of an embodiment of a process for processing a digitized aerial surveillance signal received over the FM communication link of FIG. 1.

FIG. 6 is a functional block diagram of another embodiment of a system for providing a digitized aerial surveillance video for transmission over the analog FM communication link of FIG. 1.

FIG. 7 is a functional block diagram of another embodiment of a system for processing a digitized aerial surveillance video received over the analog FM communication link of FIG. 1.

In the appended figures, similar components and/or features may have the same reference label. Where the reference label is used in the specification, the description is applicable to any one of the similar components having the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION

The ensuing description provides preferred exemplary embodiment(s) only, and is not intended to limit the scope, applicability or configuration of the disclosure. Rather, the ensuing description of the preferred exemplary embodiment(s) will provide those skilled in the art with an enabling description for implementing a preferred exemplary embodiment. It being understood that various changes may be made in the function and arrangement of elements without departing from the spirit and scope as set forth in the appended claims.

In one embodiment, the present disclosure provides an aerial surveillance apparatus for processing an analog aerial surveillance video. The processing includes digitizing the analog surveillance video in a way to be transmitted efficiently over an analog (frequency modulation) FM communication link. The aerial surveillance apparatus can be combined with existing analog video equipment, e.g., analog video cameras and/or analog FM transceivers, to communicate digitized aerial surveillance video over the analog FM communication link. By combining the aerial surveillance apparatus with existing equipment, costs for replacing the existing equipment with new digital video equipment can be avoided, for example. Further, digitizing the analog video provides benefits such as, for example, encryption, forward error correction (FEC) and more efficient use of bandwidth. More efficient use of bandwidth can provide improved signal to noise ratio (SNR), and thereby improved range of communication. In addition, more efficient use of bandwidth can allow for multiple video signals being communicated over the same bandwidth occupied by a single analog video signal. In addition, extraneous data signals including flight control information, telemetry, camera pointing, aperture and focusing information, and other metadata can be combined with the digitized video and transmitted over the analog FM video communication link. Additionally, the extraneous data could include other video, audio or other data streams.

In another embodiment, the present disclosure provides an aerial surveillance apparatus for processing a digitized aerial surveillance signal received over an analog FM video communication link. The digitized aerial surveillance signal can include one or more digitized video signals and/or digital data signals. These combined signals can be processed such that they occupy the same or less bandwidth than a single analog video signal.

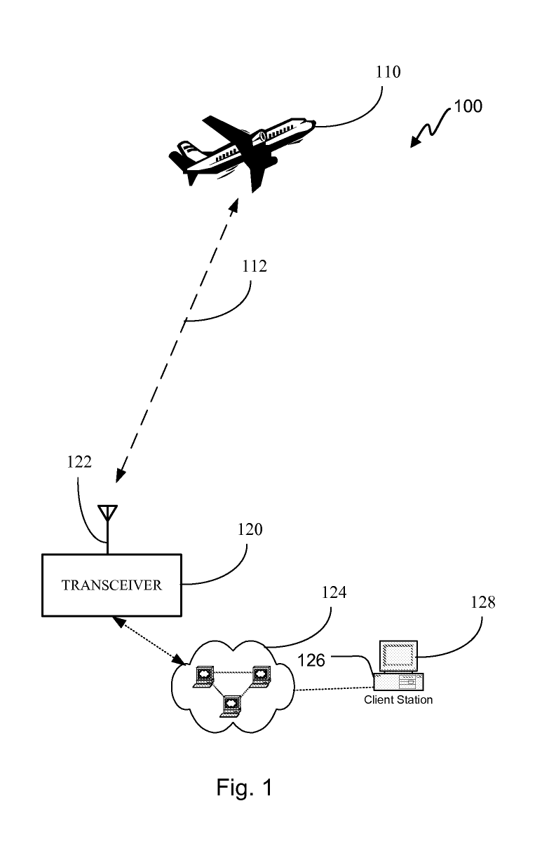

Referring first to FIG. 1, an aerial surveillance system 100 is shown that includes an aerial vehicle 110 and a ground transceiver 120 that includes an antenna 122. The aerial vehicle 110 can be a manned aerial vehicle (MAV) or an unmanned aerial vehicle (UAV). The aerial vehicle 110 includes an aerial surveillance system including an analog video camera and an analog FM video transmitter. The aerial vehicle 110 and the ground transceiver communicate via a wireless analog FM communication link 112. The communication link in this example is a two way or bi-directional communication link.

The ground transceiver 120 is connected to analog video equipment (not shown). In addition, the ground transceiver 120 can be connected to flight control equipment (not shown) for communicating flight control information to the aerial vehicle 112 via the communication link 112. This is typically done via an airborne control radio that is on a separate channel from the analog FM video communication link.

The ground transceiver 120 receives aerial surveillance video signals from the aerial vehicle via the communication link 112. The ground transceiver 120 is connected to a communication network 124. The communication network 124 can include wired and or wireless networks. Wireless networks can include mobile phone networks (e.g., GSM, CDMA, TDMA, LTE, etc.), local area networks (LANs) (e.g., IEEE 802.11x), personal area networks (PANs) (e.g., IEEE 802.15/Bluetooth), WiMax networks (IEEE 802.16x), etc. Wired networks can include Ethernet, telephone, cable, etc.

The ground transceiver 120 can communicate the video signals and/or data signals received over the communication link 112 over the communication network to other remote computers such as a client station 126. The client station 126 includes video equipment including a video display 128. There is only one client station 126 shown in FIG. 1, but more could be connected to the communication network 124 in one or more locations across the communication network 124. In this way, the video can be shared with devices that do not have a receiver or are out of range of the aerial vehicle 110.

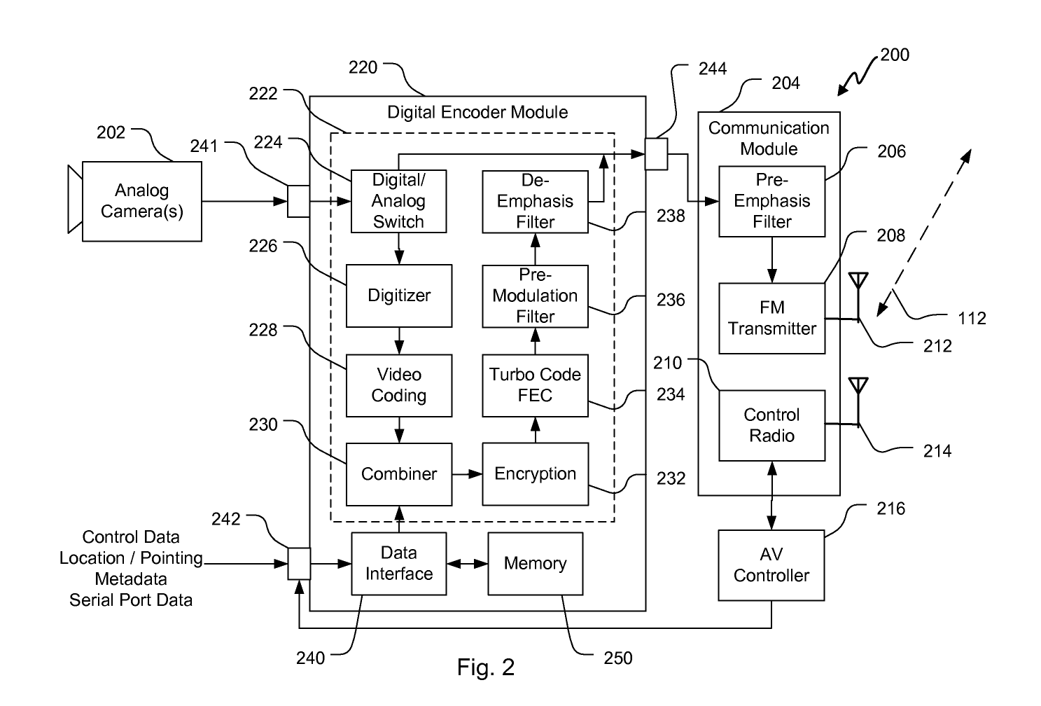

Referring to FIG. 2, an airborne system 200 for providing a digitized aerial surveillance video for transmission over the analog FM communication link 112 of FIG. 1 is shown that includes an analog video camera 202, a communication module 204 and a digital encoder module 220. The airborne system 200 can be included in the aerial vehicle 110 of FIG. 1, for example. The analog video camera 202 and the communication module 204 can be existing equipment on the aerial vehicle 110 and the digital encoder module 220 can be retrofitted in certain applications. The digital encoder module 220 includes elements for converting an analog video signal from the analog video camera 202 into a digital video signal for transmission via the analog FM transmitter 208. In addition, the digital encoder module 220 includes elements for combining the digital video signal with other digital data signals to form a combined digital signal to be transmitted via the analog FM transmitter 208.

The analog video camera 202 outputs a standard analog video signal such as the National Television System Committee (NTSC) standard, the European SECAM standard, or the phase alternating line (PAL) standard. Without the digital encoder module 220 installed in an aerial vehicle 110, the output of the analog camera 202 feeds directly into the communication module 204. The analog video camera 202 can output color video, black and white video, infrared video, and/or night vision video.

The communication module 204 includes a pre-emphasis filter 206, an analog FM transmitter 208, and an airborne control radio 210. The analog FM transmitter includes an antenna 212 and the control radio 210 includes an antenna 214. The pre-emphasis filter 206 serves to mitigate noise introduced to the analog signal by the over-the-air channel of the communication link 112 by amplifying higher frequencies of the baseband input signal. The noise introduced to an analog signal over the communication link 112 has more power at higher frequencies than it does at lower frequencies. The pre-emphasis filter 206 increases the amplitudes of higher frequencies in a band of frequencies than at lower frequencies in the band of frequencies. The increase in amplitude at certain frequencies is generally proportional to the noise amplitude at that frequency. In this way, the noise affects all frequencies in a similar manner and the overall SNR of the analog signal is improved. At the receive end of the communication link, the FM receiver has a de-emphasis filter that counteracts the pre-emphasis filter 206 and the analog video signal is returned to its normal amplitude at all frequencies as will be explained below.

The airborne control radio 210 is a two-way radio that communicates with a corresponding ground control radio at the ground transceiver 120. The airborne control radio 210 is typically a relatively low data rate radio (e.g., 200 kbps). The data received by the airborne control radio 210 can include flight plans, camera pointing, aperature or focusing instructions, etc. This received data is communicated from the airborne control radio 210 to the aerial vehicle (AV) controller 216. The AV controller 216 couples the received control information to the other systems of the aerial vehicle 110 (e.g., a camera control system, an autopilot, a navigation system, etc.).

The AV controller 216 can also provide control data to the airborne control radio 210 to be transmitted to the ground transceiver 120. Such transmitted control data could include current heading of the aerial vehicle 110, current speed, camera pointing directions, equipment status information, etc. Further, the data channel at a data input port 242 can be used to send additional information on the downlink by the AV controller 216 or other equipment within the aerial surveillance system 110.

The digital encoder module 220 includes a processor 222, a data interface 240 and memory 250. Various elements of the processor 222 can be implemented with one or more application specific integrated circuits (ASICs), digital signal processors (DSPs), digital signal processing devices (DSPDs), programmable logic devices (PLDs), field programmable gate arrays (FPGAs), controllers, micro-controllers, microprocessors, electronic devices, other electronic units, modules, discrete circuits, or any combination thereof. The data interface 240 communicates data between external devices, via an input port 242, and the processor 222 and/or the memory 250. The memory 250 may be long term, short term, volatile, nonvolatile, or another type of memory and is not limited to any particular type of memory or number of devices.

The processor 222 includes a digital/analog switch 224, a digitizer 226, a video coding module 228, a combiner 230, an encryption module 232, a Turbo Code forward error correction (FEC) module 234, a pre-modulation filter 236 and a de-emphasis filter 238. The processor 222 is customized with software to specialize the processor to perform certain functions generally denoted by some of the blocks. A general purpose and/or DSP may be used to implement some or all of the processor 222.

The digital/analog switch 224 is coupled to an video input port 241 that is connected to the analog video camera 202. The digital/analog switch 224 is controlled to direct the analog video signal received from the analog video camera 202 in one of two directions, depending on the capabilities of the receiver that the analog video is being transmitted to at the ground transceiver 120. If the receiver is only capable of receiving and displaying analog video signals, then the analog/digital switch 224 is controlled to direct the received analog video signal to a composite output port 244 and directly to the pre-emphasis filter 206 of the communication module 204. In this way, a ground transceiver 120 that has not been upgraded to include receiver modules capable of decoding the digital video signal of the digital encoder module 220 can still function with an AV that includes the digital encoder module 220.

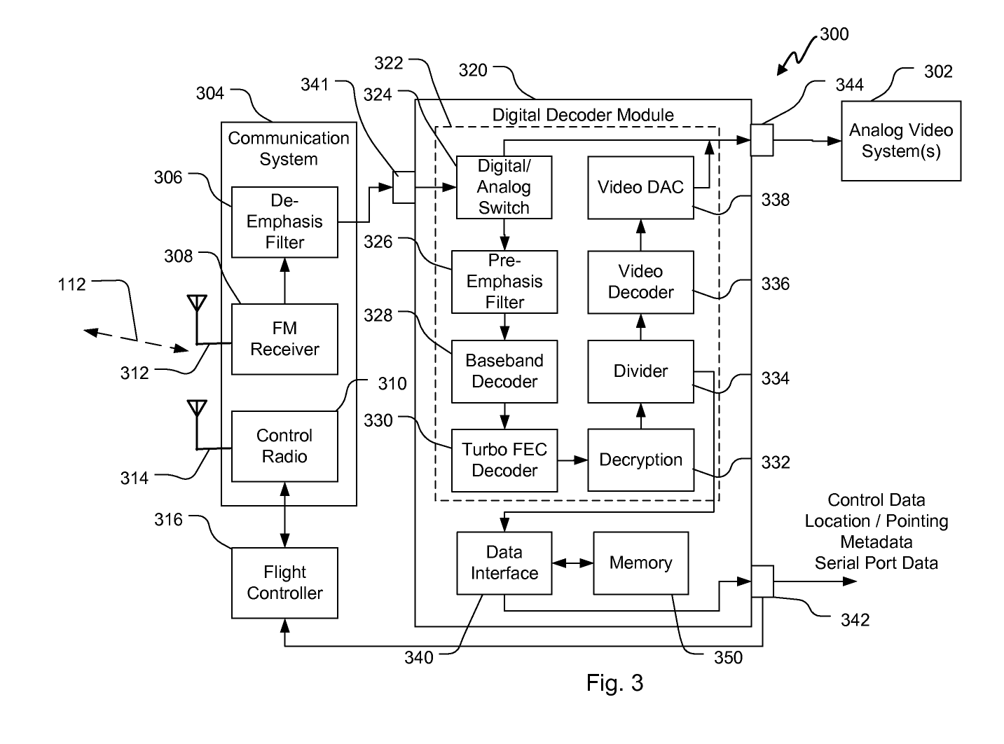

If the targeted ground transceiver 120 is capable of decoding the digital video signal produced by the digital encoder module 220, then the digital/analog switch is controlled to direct the analog video signal to the digitizer 226. The analog/digital switch 224 can be implemented with hardware or software or a combination thereof. The analog/digital switch 224 can be controlled based on information received by the airborne control radio 210 and/or by data received with the corresponding receiver portion of the digital decoder module (see FIG. 3 below).

The digitizer 226 can utilize any digital video standard such as digital video (DV), high definition video (HDV), high definition television (HDTV) and others. The digitized video signal at this stage is a raw uncompressed digital video.

After the video is digitized, it is passed to the video coding module 228. Preferably the video coding module includes a video compression system such as H.264, MPEG-2 or MPEG-4. The video coding module 228 can include multiple compression algorithms that are controllable via data received from a ground transceiver 110. The data could control bit rates, compression options, resolution, frame rates, etc. The video compression algorithms reduce redundancy in the video sequence and thereby reduce the bandwidth necessary to transmit the video. Compression algorithms like these result in acceptable video signals with as few as 2 Mbps.

After video coding, the compressed video signal is passed to the combiner 230, where it is combined with other digital data received on the data input port 242 or produced within the digital encoder module 220. The combiner 230 is coupled to the data interface 240 to receive digital data extraneous to the digitized video signal. The extraneous data to be transmitted can include navigational data such as latitude, longitude, altitude, speed, etc. Other extraneous data can include various metadata for engine performance, fuel remaining, loads due to aerodynamic buffeting, etc. In addition, the other digital data can include digital video signals, e.g., from digital video cameras on the aerial surveillance system 110.

The combiner packetizes the digitized video signal and the extraneous data into packets and includes header information. The header information includes data identifying which data stream the packet body contains. This header information is used by the receiver to reconstruct the different streams of data. The combiner 230 passes the combined packetized bit stream to the encryption module 232. The combiner 230 could perform compression on the extraneous data in some embodiments.

Some embodiments could omit the encryption module 232 if the data being transmitted is not secret, sensitive, private or valuable. Encryption can protect the information from being intercepted and used by persons that are not entitled to use the information. The different data streams can be encrypted with different algorithms thereby offering different levels of protection. For example, the extraneous data may be encrypted with a first algorithm and the video stream encrypted with a second algorithm. The encryption module 232 can use encryption algorithms such as AES, DES, Triple DES, Blowfish, classified algorithms, etc.

After encryption, the digital data stream is passed to the Turbo Code FEC module 234. The FEC code does not have to be a turbo code, but turbo codes are used in this embodiment. Different portions of the digital signal can be coded at different coding rates in order to provide different levels of protection for the different portions. The aggregate turbo code is about a 4/5 rate such that the code bits comprise about 20% of the aggregate bit rate (5 aggregate bits for every 4 bits of useful information bits) in this embodiment. Other aggregate code rates can be used depending on the channel conditions.

Adaptive coding and modulation could be used in various embodiments. Where the data rate to support the digitized video and extraneous data is not using the full data throughput of the digital encoder module 220 and communication module, modulation-code points can be adjusted to maximize SNR. For example, for a 2 Mbps data rate on a channel that supports 5 Mbps could have much more robust coding to increase SNR with the unused bandwidth. Some embodiments could increase or decrease the bit rate consumed by the compressed video produced by the video coding block 228 to allow more or less bandwidth for a different modulation-code point. For example, where the ground transceiver 120 experiences an unacceptable signal strength, the compression of the video could be increased to allow a more conservative modulation-code point to boost the SNR.

After the turbo code FEC module 234 has processed the combined digital data/video signal, the bits are passed to the pre-modulation filter 236. The bits stream that is passed to the pre-modulation filter 236 is represented by a stream of square or binary pulses of amplitude 0 or 1, depending on the bit value. Square waves have very sharp transition edges when the value of the amplitude changes (e.g., from 0 to 1 or from 1 to zero for a binary square wave). Since the FM transmitter 208 varies the frequency of the carrier wave based on the amplitude of the waveform being modulated, the frequencies would need to be adjusted quickly, which causes the bandwidth of the modulated waveform to be quite large. For this reason, the pre-modulation filter 236 shapes the square waves with a smoother pulse, for example, a Gaussian shaped pulse.

Gaussian shaped pulses have about one quarter of the bandwidth, when modulated by the FM transmitter 208, compared to the bandwidth of the square wave pulses. Put another way, the frequency spectrum of modulated square waves rolls off at one quarter the rate of the frequency spectrum of the modulated Gaussian pulses. Where the Gaussian pulse frequency spectrum is down 60 db from the peak, the square wave frequency spectrum is only down 20 db, for example. This helps improve the SNR of the signal transmitted by the FM transmitter such that a single digital video signal with Gaussian pulses, that occupies about 5 MHz bandwidth, has about 4 times the SNR as a digital video signal with square waves that occupies about 20 MHz in one embodiment. This results in the Gaussian pulse signal having about four times the range as the square wave signal. Alternatively, four-video signals (of 5 MHz each) could be transmitted over the same range as a single square wave signal.

In addition to shaping the bitstream pulses with the Gaussian filter, the pre-modulation filter 236 also modulates the bits of the Gaussian filtered bitstream pulses into baseband symbols. Preferably the pre-modulation filter 236 uses frequency shift keying (FSK). FSK is a frequency modulation scheme in which digital information is transmitted through discrete frequency changes of a carrier wave. The simplest FSK is binary FSK (BFSK). BFSK uses two discrete frequencies to transmit binary bits (0s and 1s). Other forms of FSK, e.g., multiple frequency shift keying (MFSK), can use more than two frequencies to represent multiple bits of information. Four frequencies could be used to represent two bits of data, 8 frequencies could be used to represent 3 bites, etc.

The Gaussian filtered FSK baseband signal is passed from the pre-modulation filter to the de-emphasis filter 238. The de-emphasis filter 238 counteracts the pre-emphasis filter 206 associated with the FM transmitter 208. Data transmission over an analog FM communication link, unlike analog signals such as the analog video signal, do not exhibit the same increased noise at higher frequencies than at lower frequencies. The noise is effectively evened out over all bits by the FEC coding, interleaving and other encoding techniques. The pre-emphasis filter 206 does not improve the SNR of the transmitted data signal, so it is not used. Further, the pre-emphasis filter 206 adversely increases the bandwidth of the transmitted signal. For these reasons, the de-emphasis filter 238 is applied to the baseband signal to counteract the pre-emphasis filter 206 and improve performance for one embodiment.

In one embodiment, the de-emphasis filter 238 can be omitted or bypassed when the communication module 204 does not have a pre-emphasis filter 206, or the when the pre-emphasis filter has been disabled. In one aspect of this embodiment, the de-emphasis filter can be disabled when connected to the specific communication module 204. In another aspect, the de-emphasis filter 238 can be reprogrammable, e.g., with control data received from the airborne control radio 210 or from data received over the combined digital video/data signal received by the FM receiver.

The de-emphasis filter 238 passes the combined data/video signal to the pre-emphasis filter 206 of the communication module 204 via the composite output port 244. The pre-emphasis filter 206 filters the combined digital video/data signal and passes it to the FM transmitter 208 which transmits the combined digital video/data signal as if it were a normal analog video signal. In some embodiments, the pre-modulation filter 236 and the de-emphasis filter 238 are configured such that the combined digital video/data signal that is passed to the communication module 204 measures one volt peak to peak. This is done because most FM transmitters are designed to receive an input analog signal that measures one volt peak to peak. Other embodiments could use other voltage swings.

Referring to FIG. 3, a ground system 300 for processing a digitized aerial surveillance video, such as provided by the airborne system 200, that was received over the analog FM communication link 112 is shown. The ground system 300 includes an analog video system 302, a communication system 304, and a digital decoder module 320. In one embodiment, the ground system 300 is included in the ground transceiver 120 of the aerial surveillance system 100 of FIG. 1. The analog video system 302 and the communication module 304 can be existing equipment in the ground transceiver 120 and the digital decoder module 320 can be retrofitted.

The digital decoder module 320 is a receiver module associated with the digital encoder module 220 of FIG. 2. The digital decoder module 320 includes elements for processing a digital video signal produced by the digital encoder module 220 to produce an analog video signal compatible with the analog video system 302. In addition, the digital decoder module 320 includes elements to process a combined digital video/data signal produced by the digital decoder module 320 to separate the digital video signal from any extraneous data.

The communication system 304 includes a de-emphasis filter 306, an analog FM receiver 308 and a ground control radio 310. The analog FM receiver includes an antenna 312 and the ground control radio 310 includes an antenna 314. The analog FM receiver 308 can receive a digital video signal that was produced by the digital encoder module 220 discussed above and demodulate it the same as if it were an analog video signal. The digital signal can be a digital video signal a digital data signal or a combined digital video and data signal. In any case, the digital signal produced by the digital encoder module 220 is demodulated from a carrier signal by the analog FM receiver 308 to reproduce the baseband digital signal.

After demodulation by the analog FM receiver 308, the digital signal is optionally passed to the de-emphasis filter 306. The de-emphasis filter 306, when paired with the pre-emphasis filter 206 of the analog FM transmitter 208 discussed above, serves to mitigate noise introduced to the analog video signal by the over the air channel of the communication link 112, when operated in that mode. The de-emphasis filter 306 is coupled to a composite input port 341 of the digital decoder module 320. The de-emphasized digital signal is passed to the digital decoder module 320 via the composite input port 341.

In addition to demodulating digital signals produced by the digital encoder module 220, the analog FM receiver 308 and de-emphasis filter 306 can still receive and demodulate analog video signals where the digital encoder module 220 is not present. These analog video signals can also be passed to the digital decoder module 320 that would bypass processing of the analog video signal. The present embodiment does not pass analog video signals over the communication link 112—instead passing a digitally encoded signal that can include both a digital video stream(s) and/or extraneous data.

The ground control radio 310 is a two-way radio that communicates with a corresponding airborne control radio 210 at the transmitter, e.g., the airborne control radio 210 shown in FIG. 2. The ground control radio 310 is typically a relatively low date rate radio (e.g., 200 kbps). In this example, the ground control radio 310 is coupled to a flight controller module 316. The flight controller module 316 can provide control data including flight plans or camera pointing, aperture, or focusing instructions, to be transmitted to the aerial vehicle 110. The ground control radio 310 can also receive status, control and/or telemetry information from the aerial vehicle 110.

The digital decoder module 320 includes a processor 322, a data interface 340 and memory 350. Various elements of the processor 322 can be implemented with one or more application specific integrated circuits (ASICs), digital signal processors (DSPs), digital signal processing devices (DSPDs), programmable logic devices (PLDs), field programmable gate arrays (FPGAs), controllers, micro-controllers, microprocessors, electronic devices, other electronic units, or a combination thereof. The data interface 340 communicates data from the processor 322 and/or the memory 350 to external devices, via an I/O port 342. The memory 350 may be long term, short term, volatile, nonvolatile, or another type of memory and is not limited to any particular type of memory or number of devices.

The processor 322 includes a digital/analog switch 324, a pre-emphasis filter 326, a baseband decoder module 328, a Turbo FEC decoder 330, a decryption module 332, a divider module 334, a video decoder module 336 and a video digital to analog conversion (DAC) module 338. The processor 322 is customized with software to specialize the processor to perform certain functions generally denoted by some of the blocks. A general purpose and/or DSP may be used to implement some or all of the processor 322.

The digital/analog switch 324 is coupled to the composite input port 341 that is connected to the communication module 304. The digital/analog switch 324 is controlled to direct the demodulated signal received from the communication module 304 in one of two directions, depending on the content of the demodulated signal. If the demodulated signal contains analog video, then the analog/digital switch 324 is controlled to direct the received analog video signal to an video output port 344 and directly to the analog video systems 302. If the demodulated signal contains digital content (e.g., digital video and/or digital data), then the analog/digital switch 324 is controlled to direct the digital signal to the pre-emphasis filter 326. The analog/digital switch 324 can be hardware or software or a combination thereof. The analog/digital switch 324 can be controlled based on information received by the ground control radio 310, by data embedded in the received digital signal, or by knowledge of the capabilities of the transmitting aerial vehicle from which the signal originated.

The pre-emphasis filter serves to counteract the filtering of the de-emphasis filter 306. As discussed above, the digital encoder module 220 used a de-emphasis filter 238 to counteract the pre-emphasis filter 206 of the FM transmitter 208. This was done because digital data is not affected more by noise at higher frequencies that at lower frequencies as is an analog video signal. Similarly, the pre-emphasis filter 326 counteracts the filtering of the de-emphasis filter 306.

In one embodiment, the pre-emphasis filter 326 can be omitted or bypassed when the communication module 304 does not have a de-emphasis filter 306, or the when the de-emphasis filter 306 has been disabled. In one aspect of this embodiment, the pre-emphasis filter 326 can be disabled when connected to the specific communication module 304. In another aspect, the pre-emphasis filter 326 can be reprogrammable, e.g., with control data received from the ground control radio 310, from data received over the combined digital video/data signal received by the FM receiver 308, or from knowledge of the capabilities of the aerial vehicle 110 transmitting the received signal.

The pre-emphasis filter 326 passes the digital baseband signal to the baseband decoder 328. The baseband decoder 328 is configured to use decoding techniques such as, for example, matched filtering, to demodulate the baseband symbols into information bits. The baseband decoder can provide a hard decision value for each bit (e.g., a 0 or a 1), or a soft decision value (e.g., a decimal value between zero and one). As discussed above, preferably the base band symbols are Gaussian FSK symbols. The FSK symbols can represent 1 bit/symbol, 2 bits/symbol, 3 bits/symbol or more.

The baseband decoder 328 passes the hard or soft decision decoded bits to the turbo FEC decoder 330. The turbo FEC decoder 330 can use algorithms such as a Viterbi decoder to decode the FEC code. FEC codes other than turbo codes can be used, but turbo codes are preferred. Bits that are not decodable, e.g., due to noise distortion or loss of signal, are omitted or a best guess to the value is made. The turbo FEC decoder 330 can support decoding different FEC codes and different decoding rates for different portions of the data.

The turbo FEC decoder 330 passes the decoded bit stream to the decryption module 332 which decrypts the encrypted portions of the bit stream. As discussed above, different portions of the bit stream can be encrypted with different algorithms or different strengths of encryption. The type of decryption algorithm used depends on the encryption algorithm used. Header information in packets of the bit stream can be used to identify the proper algorithm to use.

Upon decryption, the bit stream is passed to the divider module 334. The divider module examines header information of packets in the bit stream to identify whether the packets belong to one or more digital video signals, or one or more digital data signals. If packets are identified as belonging to one or more digital video signals, the divider 334 forwards these video packets to the video decoder 336. If the packets belong to one or more digital data signals, the packets are forwarded to the data interface 340. The data interface 340 then forwards the digital data signal packets to one or more external devices via an output 342, and/or to the memory 350 for later use. The digital data signals can include data such as telemetry data, location data, metadata regarding systems on board the aerial vehicle, etc.

The video decoder 336 processes the video packets received from the divider 336. The processing can include one or more decompression algorithms such as H.264, MPEG-2, MPEG-4, etc. The video decoder 336 passes the decoded video signal(s) to the video DAC 338. The video DAC 338 converts the digital video signal(s) into analog signals such as NTSC, SECAM and/or PAL. These analog video signals are then passed, via the video output 344, to the analog video system(s) 302 for display and/or analysis.

In one embodiment, the digital encoder and decoder modules 220, 320 are included in the same aerial surveillance device. In this way, the aerial surveillance device can both receive and transmit (full duplex) digital video signals, digital data signals and/or combined digital video/data signals. This full duplex embodiment can be used in the aerial vehicle 110 or the ground transceiver 120. In one aspect, with this full duplex ability, the control radios 210, 310 can be disabled or removed. In this aspect, the AV controller 216 or the flight controller 316 communicates with the data interface 240 or the data interface 340 (the data interfaces 240 and 340 can be the same data interface), respectively, and the data is transmitted or received via the analog FM transmitter 208 or FM receiver 308, respectively.

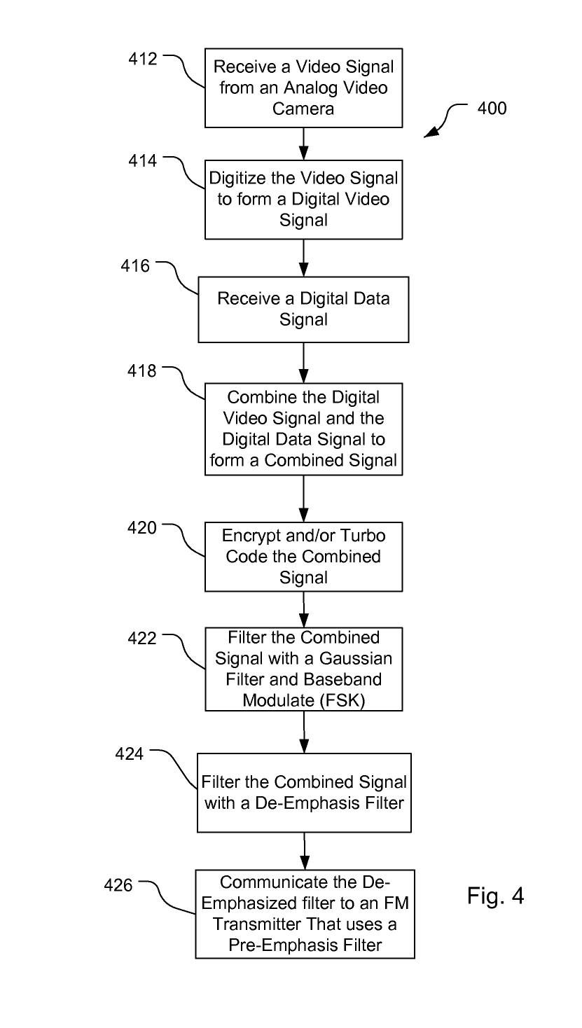

Referring to FIG. 4, a process 400 for providing a digitized aerial surveillance video for transmission over the analog FM communication link 112 is shown that includes the stages shown. The process 400 is exemplary only and is not limiting. The process 400 may be modified, e.g., by adding, removing, or rearranging the stages shown. With further reference to FIG. 2, the process 400 starts at stage 412 where the digital encoder module 220 receives a video signal from the analog video camera 202. The video signal can be any standardized analog signal such as NTSC, SECAM and/or PAL.

More than one analog video signal can be received simultaneously at stage 412. For example, an aerial vehicle 110 may have multiple cameras, such as a forward facing camera for viewing upcoming weather formations, a narrow field of view camera, a wide field of view camera, and others. The multiple analog video signals can be processed serially or in parallel by the processor 222 or by multiple processors 222.

At stage 414, the video signal is digitized to form a digital video signal. The digitization can be any digital video standard such as digital video (DV), high definition video (HDV), high definition television (HDTV) and others. The digital video signal at this stage is a raw uncompressed digital video.

At stage 416, the data interface 240 receives one or more digital data signals. The digital data signals can include metadata regarding various systems in the aerial vehicle 110, telemetry data, location data, serial port data from other computer systems in the aerial vehicle 110, or digital video signals (e.g., compressed H.264 or MPEG-x signals) from digital video cameras on board the aerial vehicle 110.

At stage 418, the combiner 230 combines the digital video signal(s) and the digital data signal(s) to form a combined signal. The combiner 230 packetizes the different signals and attaches header information to the packets. The header information identifies the digital data signal to which each packet belongs.

At stage 420, the combined signal is encrypted by the encryption module 232 and/or FEC coded by the turbo code FEC module 234. Different packets of the combined signal can be encrypted with different encryption algorithms, with different encryption keys, with different strengths of encryption, or not encrypted at all. The encryption module 232 can use header information to determine which encryption algorithms and/or encryption keys to use at stage 420. The different digital signals in the combined signal can also be FEC coded with different levels of FEC coding. More important portions of the digital signal can be FEC coded at higher coding rates in order to give a better chance of these portions getting received without errors.

Upon completion of encryption and/or FEC coding at the stage 420, the process 400 continues at stage 422 where the pre-modulation filter 236 filters the combined signal with a Gaussian filter, in order to smooth the pulses as discussed above, and baseband modulates the smoothed pulses with FSK modulation. The FSK modulation can be binary, where each baseband FSK symbol represents 1 bit. Alternatively, each FSK symbol could represent 2, 3, 4 or more bits.

At stage 424, the de-emphasis filter 238 filters the combined signal to decrease amplitudes of higher frequencies within a band of frequencies more than amplitudes of lower frequencies within the band of frequencies. As discussed above, this is done to counteract the pre-emphasis filtering performed by the analog FM transmitter 208 that will be transmitting the combined signal. The de-emphasis filtering at stage 424 can be omitted if the analog FM transmitter does not have a pre-emphasis filter or if the pre-emphasis filter is disabled.

At stage 426, the processer 222 communicates the combined signal (de-emphasized or not) to the analog FM transmitter 208 to be transmitted. The combined signal that is communicated to the analog FM transmitter 208 has an amplitude of one volt peak-to-peak, or whatever voltage amplitude the analog FM transmitter 208 is designed to receive.

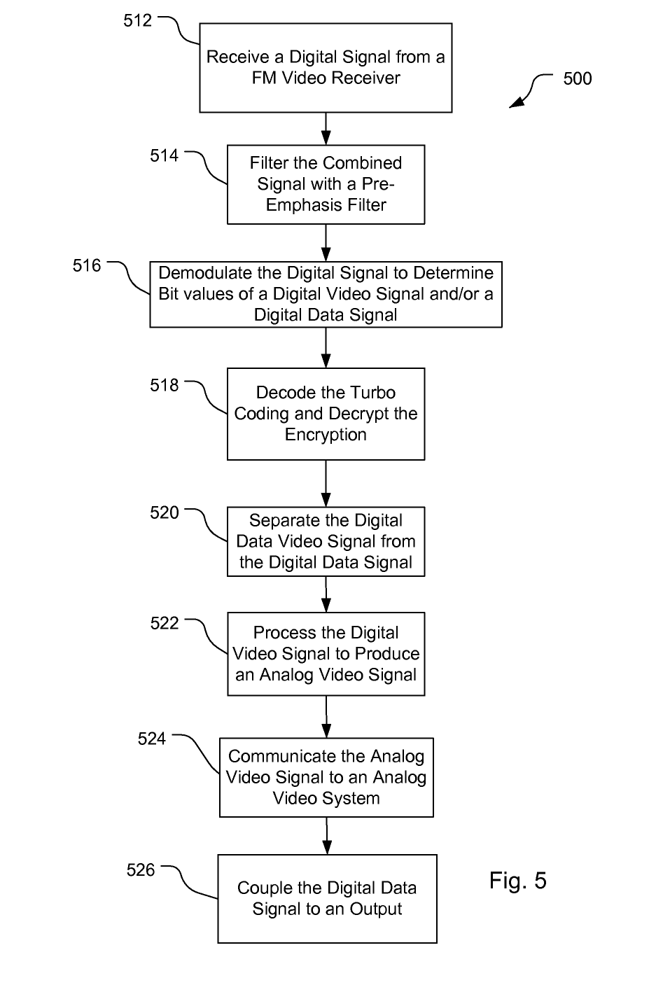

Referring to FIG. 5, a process 500 for processing a digitized aerial surveillance signal (e.g., one produced by the digital encoder module 220 using the airborne system 200) received over the FM communication link 112 is shown that includes the stages shown. The process 500 is exemplary only and is not limiting. The process 500 may be modified, e.g., by adding, removing, or rearranging the stages shown. With further reference to FIG. 3, the process 500 starts at stage 512, where the digital decoder module 320 receives a digital signal from a FM video receiver.

The digital signal received at stage 512 has been demodulated from a carrier signal by the FM video receiver. In some cases, the digital video signal was filtered with a de-emphasis filter of the FM video receiver, where the de-emphasis filter decreases amplitudes of higher frequencies within a band of frequencies more than amplitudes of lower frequencies within the band of frequencies. Further, the digital signal received at stage 512 can be one or more digital video signals, one or more digital data signals, or a combined signal including one or more digital video signals and one or more digital data signals.

If the FM video transmitter from which the digital signal was received included a de-emphasis filter, then the process 500 continues at stage 514, otherwise the process 500 continues at stage 516. At stage 514, the pre-emphasis filter 326 filters the digital signal so as to counteract the de-emphasis filter of the FM video receiver.

At stage 516, the baseband decoder 328 demodulates the digital signal to determine bit values of baseband symbols of the one or more digital video signals and/or the one or more digital data signals. The baseband decoder 328 can use the techniques discussed above. The baseband symbols can represent 1, 2, 3, 4 or more bits.

At stage 518, the turbo FEC decoder 330 decodes the turbo FEC coded data in the digital signal. Different portions of the digital signal can be encoded, and decoded, using different coding algorithms and different coding rates. Also at stage 518, the decryption module 332 decrypts the data that is encrypted. Different portions of the data signal can be encrypted, and decrypted, with different encryption algorithms, different encryption/decryption keys, and different strengths of encryption.

At stage 520, the divider 334 separates the digital signal, if necessary, into one or more digital video signals and/or one or more digital data signals. The divider 334 forwards the digital data signals to the data interface 340. The divider 334 forwards the digital video signals to the video decoder 336.

At stage 522, the video decoder 336 and the video DAC 338 process the one or more digital video signals received from the divider 334 to produce one or more analog video signals. The processing done by the video decoder 336 can include video decompression using H.264, MPEG-2, and/or MPEG-4. The video DAC 338 can convert standard digital video such as DV, HDV and/or HDTV into one or more analog standards such as NTSC, SECAM and/or PAL.

At stage 524, the converted analog video signals are communicated via the video output 344 to the analog video system(s) 302 for display and/or analysis. At stage 526, the digital data signal(s) received from the divider 334 are coupled, via the output 342 to one or more external devices such as, for example, flight controller 316, computers, digital video systems, etc.

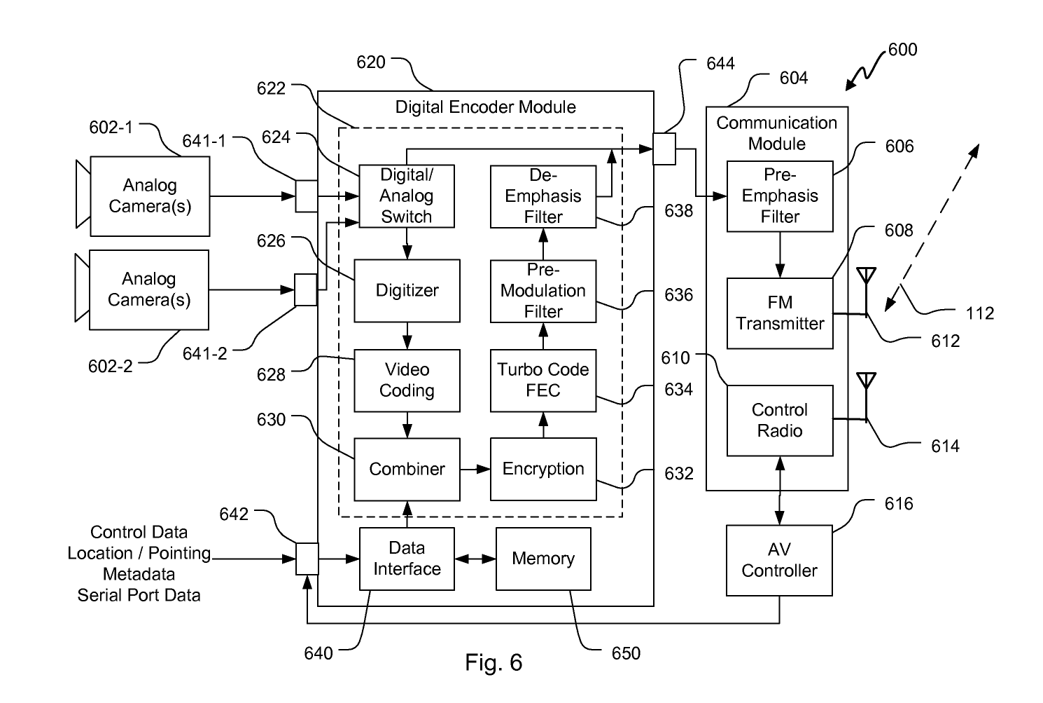

Referring to FIG. 6, an airborne system 600 for providing a digitized aerial surveillance video for transmission over the analog FM communication link 112 is shown that includes two analog video cameras 602-1 and 602-2. The airborne system 600 could have more than two analog video cameras. The analog video signals of the analog video cameras 602-1 and 602-1 are received by the digital encoder module 620 via video inputs 641-1 and 641-2, respectively. The various elements 624 through 638 of the digital encoder module 620 are similar to the modules 224 through 238, respectively, of the digital encoder module 220 of FIG. 2. The digital/analog switch 624, the digitizer 626 and the video coding module 628 can process the two analog video signals in parallel or in series. The combiner then combines the two digitized video signals with any data received from the data interface 640. The remaining elements 632 through 638 process the combined signal in the same way as described above in reference to the elements 232 through 238 of FIG. 2.

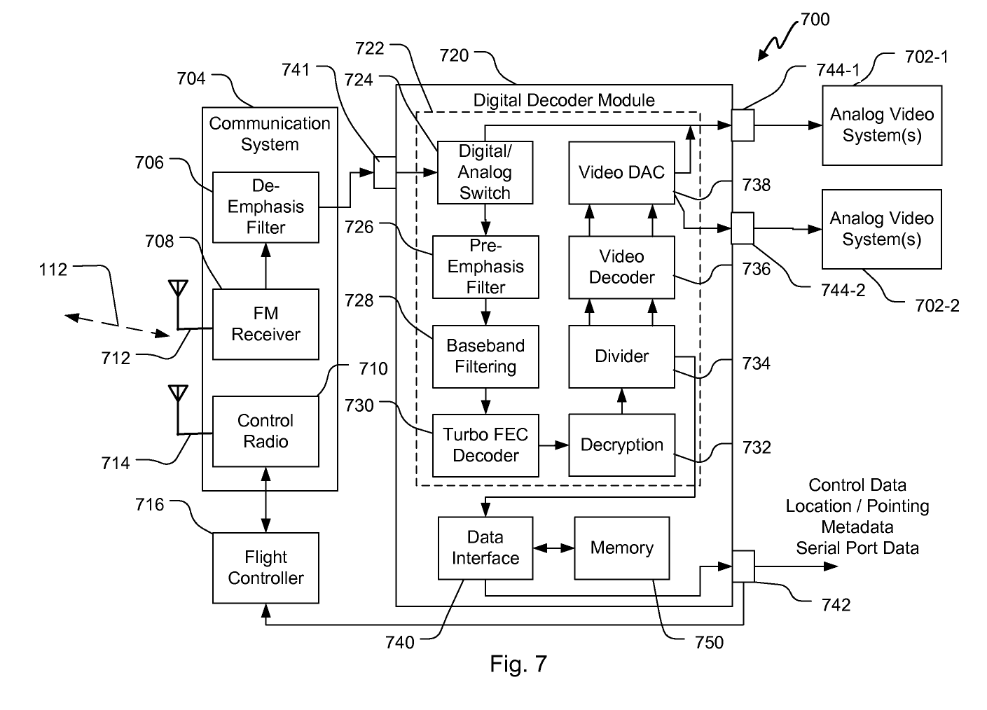

Referring to FIG. 7, a ground system 700 for processing a digitized aerial surveillance video received over the analog FM communication link 112 is shown that produces two analog video signals. The ground system 700 includes two analog video systems 702-1 and 702-2. The ground system 700 can be used to receive the digital signal produced by the airborne system 600 which includes two digital video signals. The two digital video signals are contained in a combined digital signal received by an FM receiver 708.

The FM receiver 708 demodulates the combined digital video signal from a carrier. The de-emphasis filter 706 functions similarly to the de-emphasis filter 306 of the ground system 300 discussed above. The digital decoder module 720 receives the combined signal via a composite input port 741 and the elements 724 through 732 function similarly as the elements 324 through 332 discussed above in reference to the ground system 300. The divider 734 separates the two digital video signals, using packet header information, into two digital bit streams (illustrated as two output arrows of the divider 334). The two digital bit streams can then be processed by the video decoder 736 and the video DAC 338 in parallel or in series. The video DAC outputs a first of the converted analog signals to the analog video system 702-1 via an video output 744-1 and outputs a second of the converted analog signals to the analog system 702-2 via an video output 744-2, respectively. The ground system 700 could have more than two digital video signals received in a single analog FM signal.

A number of variations and modifications of the disclosed embodiments can also be used. For example, some embodiment describe wireless media as between the transmitter and receiver. Other embodiments could use a wired or optical media where an analog video signal includes a digitized video signal and possibly other information. In some embodiments, the video gathering side of the communication link is in the vehicle or aircraft, but the link could be reversed where a ground station is transmitting the video. Other embodiments could use a transmitter that uses any type of modulation and not just FM as described in relation to some of the above embodiments.

While the principles of the disclosure have been described above in connection with specific apparatuses and methods, it is to be clearly understood that this description is made only by way of example and not as limitation on the scope of the disclosure.

What is claimed is:

1. An aerial surveillance apparatus for processing an analog video signal, the aerial surveillance apparatus comprising:
a first input configured to receive an analog video signal from a video camera;
a processor coupled with the analog video signal and configured to filter and digitize the analog video signal to form a de-emphasized digital signal; and
an output configured to couple to an FM video transmitter and to communicate the de-emphasized digital signal to the FM video transmitter, wherein:
the filtering of the processor decreases amplitudes of higher frequencies within a band of frequencies more than amplitudes of lower frequencies within the band of frequencies, and
the FM video transmitter filters the de-emphasized digital signal using a pre-emphasis filter that counteracts the filtering of the de-emphasis filter.

2. The aerial surveillance apparatus for processing an analog video signal of claim 1, further comprising:
a second input configured to receive a digital data signal; wherein
the processor combines the digitized video signal and the digital data signal prior to the filtering to form a combined signal, and the processor filters the combined signal to form the de-emphasized digital signal.

3. The aerial surveillance apparatus for processing an analog video signal of claim 2, wherein the processor is further configured to filter the combined signal using a Gaussian filter.

4. The aerial surveillance apparatus for processing an analog video signal of claim 1, wherein subsequent to the processor digitizing the analog video signal to form a digitized signal, the processor modulates the digitized signal using frequency-shift keying (FSK).

5. The aerial surveillance apparatus for processing an analog video signal of claim 4, wherein one baseband symbol of the FSK modulation represents at least one of one bit, two bits, three bits or four bits.

6. An aerial surveillance apparatus for processing a digital video signal to produce an analog video signal, the aerial surveillance apparatus comprising:
a first input coupled with a FM video receiver and configured to receive a digital video signal from the FM video receiver, wherein:
the digital video signal is demodulated from a carrier signal;
the digital video signal was filtered with a de-emphasis filter of the FM video receiver, and
the de-emphasis filter decreases amplitudes of higher frequencies within a band of frequencies more than amplitudes of lower frequencies within the band of frequencies;
a processor coupled with the first input and configured to:
filter the digital video signal, wherein the filtering counteracts the filtering of the de-emphasis filter of the FM video receiver, and
process the digital video signal to produce an analog video signal; and
a first output coupled with the processor and configured to couple to an analog video system and to communicate the analog video signal to the analog video system.

7. The aerial surveillance apparatus for processing a digital video signal to produce an analog video signal of claim 6, wherein the digital video signal is part of a combined signal received from the FM video receiver, the combined signal also including a digital data signal, the aerial surveillance apparatus further comprising:
a divider coupled with the first input and the processor and configured to separate the digital video signal from the digital data signal and to couple the digital video signal to the processor; and
a second output coupled with the divider and configured to couple the digital data signal.

8. The aerial surveillance apparatus for processing a digital video signal to produce an analog video signal of claim 6, wherein the digital video signal comprises Gaussian filtered baseband symbols representing bit values of the digital video signal.

9. The aerial surveillance apparatus for processing a digital video signal to produce an analog video signal of claim 8, wherein the baseband symbols comprise frequency-shift keying (FSK) symbols.

10. An aerial surveillance apparatus for processing an analog video signal, the aerial surveillance apparatus comprising:
a first input configured to receive the analog video signal from a video camera;
a second input configured to receive a digital data signal;
a digitizer coupled with the first input and configured to digitize the analog video signal to form a digital video signal;
a combiner coupled with the digitizer and the second input, the combiner configured to combine the digital video signal and the digital data signal to form a combined signal;
a Gaussian filter coupled with the combiner and configured to filter the combined signal to form a filtered combined signal; and
an output coupled with the Gaussian filter and configured to couple to a FM video transmitter, the output configured to communicate the filtered combined signal to the FM video transmitter.

11. The aerial surveillance apparatus for processing an analog video signal of claim 10, further comprising:
a de-emphasis filter configured to filter the combined signal to form a de-emphasized signal, wherein:
the de-emphasis filter decreases amplitudes of higher frequencies within a band of frequencies more than amplitudes of lower frequencies within the band of frequencies, and
the FM video transmitter filters the de-emphasized signal using a pre-emphasis filter that counteracts the filtering of the de-emphasis filter.

12. The aerial surveillance apparatus for processing an analog video signal of claim 10, wherein the filtered combined signal is modulated using frequency shift keying (FSK) to form a FSK modulated combined signal and the output is configured to communicate the FSK modulated combined signal to the FM video transmitter.

13. An aerial surveillance apparatus for processing a digital video signal and a digital data signal, the aerial surveillance apparatus comprising:
an input coupled with a FM video receiver and configured to receive a digital signal from the FM video receiver, the digital signal comprising Gaussian filtered baseband symbols representing bit values of the digital video signal and bit values of the digital data signal;
a processor coupled with the input and configured to process the Gaussian filtered baseband symbols to determine the bit values of the digital video signal and the digital data signal;
a divider coupled with the processor and configured to separate the digital video signal from the digital data signal;
a video processing system coupled with the divider and configured to process the digital video signal to produce an analog video signal;
a first output coupled with the video processing system and configured to couple to an analog video system and to communicate the analog video signal to the analog video system; and
a second output coupled with the divider and configured to couple the digital data signal.

14. The aerial surveillance apparatus for processing a digital video signal and a digital data signal of claim 13, wherein:
the digital video signal and the digital data signal were filtered with a de-emphasis filter of the FM video receiver,
the de-emphasis filter decreases amplitudes of higher frequencies within a band of frequencies more than amplitudes of lower frequencies within the band of frequencies, and
the processor is further configured to filter the digital video signal and the digital data signal with a pre-emphasis filter, wherein the pre-emphasis filter counteracts the filtering of the de-emphasis filter of the FM video receiver.

15. A method of processing an analog aerial surveillance video, the method comprising:
receiving a video signal from an analog video camera;
digitizing the video signal to form a digital video signal;
filtering the video signal with a de-emphasis filter to form a de-emphasized digital signal, wherein the de-emphasis filtering decreases amplitudes of higher frequencies within a band of frequencies more than amplitudes of lower frequencies within the band of frequencies; and
communicating the de-emphasized digital signal to an FM video transmitter,
wherein the FM video transmitter filters the de-emphasized digital signal using a pre-emphasis filter that counteracts the de-emphasis filtering of the de-emphasized digital signal.

16. The method of processing the analog aerial surveillance video of claim 15, further comprising:
receiving a digital data signal; and
combining the digital video signal and the digital data signal prior to the filtering to form a combined signal,
wherein the filtering comprises filtering the combined signal to form the de-emphasized digital signal.

17. The method of processing the analog aerial surveillance video of claim 16, further comprising filtering the combined signal using a Gaussian filter.

18. A method of processing an analog aerial surveillance video, the method comprising:
receiving an analog video signal from a video camera;
receiving a digital data signal;
digitizing the analog video signal to form a digital video signal;
combining the digital video signal and the digital data signal to form a combined signal;
filtering the combined signal with a Gaussian filter to form a filtered combined signal; and
communicating the filtered combined signal to an FM video transmitter.

19. The method of processing the analog aerial surveillance video of claim 18, further comprising filtering the video signal with a de-emphasis filter to form a de-emphasized digital signal, wherein the de-emphasis filtering decreases amplitudes of higher frequencies within a band of frequencies more than amplitudes of lower frequencies within the band of frequencies, wherein:
the communicating comprises communicating the de-emphasized digital signal to the FM video transmitter, and
the FM video transmitter filters the de-emphasized digital signal using a pre-emphasis filter that counteracts the de-emphasis filtering of the de-emphasized digital signal.

20. A method of processing a digital video signal to produce an analog video signal, the method comprising:
receiving a digital video signal from a FM video receiver, wherein:
the digital video signal is demodulated from a carrier signal;
the digital video signal was filtered with a de-emphasis filter of the FM video receiver, and
the de-emphasis filter decreases amplitudes of higher frequencies within a band of frequencies more than amplitudes of lower frequencies within the band of frequencies;
filtering the digital video signal, wherein the filtering counteracts the filtering of the de-emphasis filter of the FM video receiver;
processing the digital video signal to produce an analog video signal; and
communicating the analog video signal to an analog video system.

21. The method of processing a digital video signal to produce an analog video signal of claim 20, further comprising:
receiving a combined signal from the FM video receiver, the combined signal including the digital video signal and a digital data signal, the combined signal comprising Gaussian filtered baseband symbols representing bit values of the digital video signal and bit values of the digital data signal;
determining the bit values of the digital video signal and the data signal;
separating the digital video signal from the digital data signal; and
coupling the digital data signal to an output.
